(19) United States
(12) Patent Application Publication
(10) Pub. No.: US 2002/0006706 A1
(43) Pub. Date: Jan. 17, 2002

(54) SEMICONDUCTOR DEVICE AND METHOD OF MANUFACTURING SECICONDUCTOR DEVICE

(76) Inventors: YUKIO NISHIDA, TOKYO (JP); HIROKAZU SAYAMA, TOKYO (JP); TOSHIYUKI OISHI, TOKYO (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 09/397,098

(22) Filed: Sep. 16, 1999

(30) Foreign Application Priority Data
Apr. 23, 1999 (JP) P11-116081

(51) Int. Cl. H01L 21/336

(52) U.S. Cl. 438/299

(57) ABSTRACT

Nitrogen distributed layers 3N and 53N are formed in the vicinity of surfaces of silicon layers 3 and 53 on the silicide layer 11 and 61 sides, respectively. When ions are implanted for forming source/drain regions 9 and 59, a dopant is also implanted into the silicon layers 3 and 53. Consequently, a boron distributed layer 3B or a phosphorus distributed layer 53P is formed in a deeper region than the nitrogen distributed layers 3N and 53N. Cobalt is deposited to cover the silicon layers 3 and 53 and p⁺-type layers 8 and 58, and silicide layers 11, 61, 10 and 60 are thus formed by a salicide reaction. Interaction of boron and phosphorus (interaction of the dopant in the silicon layer with the silicide layer during a salicide reaction) is suppressed by nitrogen in the nitrogen distributed layers 3N and 53N. As a result, a MOS transistor which comprises gate electrodes 5 and 55 having low resistances and has a predetermined threshold is manufactured. Thus, it is possible to provide a semiconductor device which can surely be operated with predetermined operating characteristics.

### BACKGROUND OF THE INVENTION

1. Field of the Invention

The present invention relates to a semiconductor device and a method of manufacturing the same, and more particularly to a MOS transistor comprising an electrode having a so-called salicide structure and a method of manufacturing the MOS transistor.

2. Description of the Background Art

In general, a CMOS transistor is applied to a semiconductor integrated circuit, thereby reducing power consumption of the same integrated circuit and keeping a greater operating margin and the like. Furthermore, a dual gate CMOS structure which can reduce a threshold voltage of a PMOS transistor comparatively easily has been employed to meet the demand for the fineness and the reduction in a voltage of a MOS transistor.

In a standard dual gate CMOS transistor, n-type polysilicon is used for a polycide gate electrode of an NMOS transistor and p-type polysilicon is used for the same gate electrode of a PMOS transistor. In this case, a surface channel type is applied to the PMOS transistor of the dual gate CMOS transistor. On the other hand, a buried channel type is applied to a PMOS transistor of a single gate CMOS transistor using the n-type polysilicon for the polycide gate electrodes of both the NMOS and PMOS transistors. Since the surface channel type transistor is more resistant to a punch through than the buried channel type transistor, it has a structure which is advantageous to make the MOS transistor fine.

A method of manufacturing a dual gate CMOS transistor according to the background art will be described below with reference to longitudinal sectional views at each of steps shown in FIGS. 17 to 21. First of all, a silicon substrate 100 is prepared. As shown in FIG. 17, an isolation oxide film 101 is formed in a predetermined region of the silicon substrate 100, and a p-type well (hereinafter referred to as a “p-well”) 102 constituting an NMOS transistor region and an n-type well (hereinafter referred to as an “n-well”) 103 constituting a PMOS transistor region are then formed.

Next, a silicon oxide film 104 is formed over a surface of the silicon substrate 100 on the well 102 and 103 sides, and a polysilicon layer 105 is then deposited by a CVD method as shown in FIG. 18. Thereafter, the polysilicon layer 105 and the silicon oxide film 104 are subjected to patterning by using a lithography technology and an anisotropic etching technology. Consequently, a polysilicon layer 105N and a silicon oxide film 104N are formed in predetermined positions on the p-well 102, and a polysilicon layer 105P and a silicon oxide film 104P are formed in predetermined positions on the n-well 103 (see FIG. 19).

After the PMOS transistor region is covered with a photoresist or the like, an n-type dopant or an impurity, for example, arsenic (As) ions are implanted into the p-well 102, thereby forming an n⁻-type layer 108 (see FIG. 19). By the same method, subsequently, a p-type dopant, for example, boron (B) ions are implanted to form a p⁻-type layer 109 in the n-well 103. The layers 108 and 109 may be formed in reverse order.

Thereafter, a TEOS oxide film is deposited to cover the whole surface of the silicon substrate 100 on the polysilicon layer 105P and 105N sides. The TEOS oxide film is subjected to anisotropic etch back, thereby forming a gate sidewall-spacer 110 on sidewalls of the polysilicon layers 105P and 105N and the silicon oxide films 104P and 104N (see FIG. 20).

Next, the PMOS transistor region is covered with the photoresist or the like. Then, an n-type dopant, for example, arsenic ions are implanted into the p-well 102, thereby forming an n⁺-type layer 111 constituting a source/drain region together with the n⁻-type layer 108. At this time, the arsenic ions are implanted into the polysilicon layer 105N at the same time so that the polysilicon layer 105N becomes an n-type (see an arsenic distributed layer 113 shown in FIG. 20). Similarly, boron ions are implanted into the n-well 103, thereby forming a p⁺-type layer 112 constituting a source/drain region together with the p⁻-type layer 109, for example. At this time, the boron ions are also implanted into the polysilicon layer 105P so that the polysilicon layer 105P becomes a p-type (see a boron distributed layer 114 shown in FIG. 20). The ions may be implanted into the wells 102 and 103 in reverse order. Then, an implanted dopant is activated by a proper heat treating step (at a temperature of about 800 to 900° C. for about 30 minutes, for example) or the like (an annealing treatment).

Subsequently, a metal such as tungsten (W) or the like is deposited to cover the whole surface of the silicon substrate 100 on the side where the polysilicon layers 105N and 105P and the like are formed. By performing a heat treatment, a silicide reaction or a salicide reaction is selectively caused in self-alignment only in a portion where tungsten and silicon are in contact with each other. Then, the unreacted tungsten deposited over the spacer 110 and the like is removed. Consequently, silicide layers 116, 118, 115 and 117 for reducing a parasitic resistance are formed on the polysilicon layers 105N and 105P, the n⁺-type layer 111 and the p⁺-type layer 112 respectively as shown in FIG. 21. An element comprising the polysilicon layers 105N and 105P and the silicide layers 116 and 118 is referred to as a “gate electrode”.

Other examples of the method of forming the silicide layer include a method of depositing a silicide material itself. In this case, a method of forming the silicide layers 118 and 116 constituting a gate electrode together with the polysilicon layers 105P and 105N comprises the steps of forming a polysilicon layer 105 (see FIG. 18), depositing a silicide material itself, and patterning the silicide layer simultaneously with the patterning of the polysilicon layer 105 (see FIG. 19).

In the case where the gate electrode of the CMOS transistor is polycide, the following problems arise.

Due to a difference in segregation coefficient between silicon and silicide, the dopant in the polysilicon layer constituting the polycide gate electrode is easily taken into the silicide layer at the heat treating step in the manufacturing process. For this reason, when the silicide material itself is deposited to form the silicide layer subsequently to the formation of the polysilicon layer, since the silicide layer is formed in the early stage of a process of manufacturing the MOS transistor, a dopant concentration in the silicon layer is sometimes reduced at the subsequent heat treating step, for example, at the time of an annealing treatment (at a temperature of about 800 to 900° C. for about 30 minutes, for example) performed after the ion implantation of the dopant into a source/drain region. In general, a diffusion speed of the dopant in the silicide is very high. For this reason, with such a structure as to share gate electrodes of PMOS and NMOS transistors constituting a dual CMOS transistor, the dopant in each polysilicon layer is rapidly diffused mutually through a silicide layer. Therefore, the above-mentioned dopant concentration is remarkably reduced. As a result, a threshold voltage of the MOS transistor greatly varies from a predetermined value in some cases. In this respect, it is apparent that the above-mentioned manufacturing method of forming a silicide layer by the salicide reaction in the final stage of the manufacturing process has a predominance.

However, when the silicide layer is formed by the salicide reaction or the silicide reaction, there is a problem in that the silicide reaction is impeded when a dopant having a high concentration is present in the silicon layer. For this reason, a resistance of the silicide layer, therefore, a resistance of the gate electrode has a higher value than that of the same silicide layer obtained when the silicon layer does not contain the dopant having a high concentration.

There has been known a phenomenon in which the silicide layer sucks boron (B) during the silicide reaction when the boron is present in the silicon layer. Therefore, in the case where the boron is used as a dopant for the PMOS transistor, a concentration of the boron in the polysilicon layer constituting the gate electrode is reduced by the silicide reaction, thereby causing the depletion of the polysilicon layer. As a result, a resistance value of the polysilicon layer obtained after the formation of the silicide, therefore, a resistance value of the gate electrode becomes greater than a desired value. Furthermore, the depletion of the polysilicon layer causes the threshold voltage of the MOS transistor to be increased. Such depletion may be caused at the subsequent heat treating step even if the silicide layer is to be formed by the deposition of the silicide material itself in the early stage of the manufacturing process.

In this case, a method of further increasing the concentration of the boron corresponding to the suction performed by the silicide layer has been proposed as one of means for avoiding the depletion of the polysilicon layer. As described above, when the polysilicon layer contains the boron having a high concentration as a dopant, the silicide reaction is impeded by the boron. Furthermore, there is a new problem in that the boron is diffused over the silicon substrate beyond a silicon oxide film forming a gate insulating film (a so-called punch through), thereby causing the threshold voltage to vary from the predetermined value.

In consideration of the above-mentioned problems, it is a first object of the present invention to provide a method of manufacturing a semiconductor device which can suppress interaction such as impediment of a silicide reaction by a dopant in a silicon layer, the sucking phenomenon of boron or the like even if a silicide layer is to be formed by a salicide reaction.

Furthermore, it is a second object of the present invention to provide a method of manufacturing a semiconductor device which can suppress a so-called punch-through of boron simultaneously with the realization of the first object.

In addition, it is a third object of the present invention to provide a semiconductor device capable of being reliably operated at a high speed with predetermined operating characteristics by the realization of the first and second objects.

### SUMMARY OF THE INVENTION

(1) A first aspect of the present invention is directed to a method of manufacturing a semiconductor device comprising the steps of (a) preparing a silicon substrate having a main surface, (b) forming, in a side of the main surface of the silicon substrate, a silicon layer which contains nitrogen at least in the vicinity of a surface of the silicon layer and into which a dopant of a predetermined conductivity type is introduced, (c) forming a metal layer to cover the whole of the main surface of the silicon substrate after the step (b), and (d) forming a silicide layer by selectively performing a silicide reaction in self-alignment with respect to a portion of the metal layer which is in contact with silicon.

(2) A second aspect of the present invention is directed to the method of manufacturing a semiconductor device according to the first aspect of the present invention, wherein the silicon layer constitutes a part of a gate electrode of a MOS transistor, the method further comprising an annealing step for a source/drain region of the MOS transistor before the step (c).

(3) A third aspect of the present invention is directed to the method of manufacturing a semiconductor device according to the first aspect of the present invention, wherein the silicon layer is at least one of a layer constituting a part of a gate electrode of a MOS transistor and a source/drain region thereof, and the nitrogen is introduced into the silicon layer by ion implantation at the step (b).

(4) A fourth aspect of the present invention is directed to the method of manufacturing a semiconductor device according to the first aspect of the present invention, wherein the silicon layer constitutes a part of a gate electrode of a MOS transistor, and the silicon layer is formed in a nitrogen containing atmosphere, thereby causing the whole of the silicon layer to contain the nitrogen therein at the step (b).

(5) A fifth aspect of the present invention is directed to the method of manufacturing a semiconductor device according to any of the first to fourth aspects of the present invention, wherein the silicon layer constitutes a part of a gate electrode of a MOS transistor, the method further comprising a step of forming an insulating film containing nitrogen all over between the silicon substrate and the silicon layer before the step (b).

(6) A sixth aspect of the present invention is directed to a semiconductor device characterized by being manufactured by the method of manufacturing a semiconductor device according to any of the first to fifth aspects of the present invention.

(7) A seventh aspect of the present invention is directed to a semiconductor device comprising a silicon layer containing a dopant of a predetermined conductivity type and including a nitrogen distributed layer at least in the vicinity of a surface of the silicon layer, and a silicide layer formed by selectively performing a silicide reaction in self-alignment with respect to a portion of a metal layer provided to cover the silicon layer, which is in contact with the surface of the silicon layer.

(8) An eighth aspect of the present invention is directed to the semiconductor device according to the seventh aspect of the present invention, wherein the dopant is ion-implanted from the side of the surface of the silicon layer to be provided in the silicon layer, and the nitrogen distributed layer is provided closer to the side of the surface of the silicon layer than the vicinity of a mean range of the implanted dopant.

(9) A ninth aspect of the present invention is directed to the semiconductor device according to the seventh aspect of the present invention, wherein the whole of the silicon layer corresponds to the nitrogen distributed layer.

(10) A tenth aspect of the present invention is directed to the semiconductor device according to any of the seventh to ninth aspects of the present invention, wherein the silicon layer and the silicide layer constitute a gate electrode of a MOS transistor.

(11) An eleventh aspect of the present invention is directed to the semiconductor device according to the tenth aspect of the present invention, further comprising a silicon substrate provided facing a surface opposite to the surface of the silicon layer, and a gate insulating layer containing nitrogen all over, provided in contact with both the silicon substrate and the silicon layer between the silicon substrate and the silicon layer.

(12) A twelfth aspect of the present invention is directed to the semiconductor device according to any of the seventh to eleventh aspects of the present invention, wherein the silicon layer and the silicide layer constitute at least one of a source electrode of a MOS transistor and a drain electrode thereof.

(1) According to the first aspect of the present invention, the silicon layer formed at the step (b) contains nitrogen in the vicinity of the surface. As compared with the case where the nitrogen is not contained, therefore, impediment of silicide reaction (or a salicide reaction) can be remarkably prevented from being caused by the dopant in the silicon layer at the step (d). Consequently, a silicide layer having a low resistance can be formed.

In particular, when the dopant is boron (B), the nitrogen in the silicon layer can sharply suppress a phenomenon in which the boron is sucked into the silicide layer during the silicide reaction. Consequently, the depletion of the silicon layer can be controlled. In this case, when the boron is previously introduced into the silicon layer at the step (b) in such an amount as to correspond to the suction of the boron, the above-mentioned depletion preventing effect can be obtained more surely. The step (b) can be applied as a step of forming a (poly)silicon layer constituting a part of a gate electrode in a MOS transistor and a step of forming a source/drain region in the MOS transistor, for example.

Accordingly, an electrode (comprising a silicon layer and a silicide layer) having a low resistance can be formed. Therefore, it is possible to provide a semiconductor device having lower power consumption than a semiconductor device comprising an electrode which includes a silicon layer having no nitrogen and a silicide layer formed in the same manner. In addition, it is possible to manufacture a semiconductor device which can be operated at a high speed by suppressing the depletion of the silicon layer.

(2) According to the second aspect of the present invention, the silicide layer has not been formed on the silicon layer constituting a part of the gate electrode during the annealing treatment for the source/drain region of the MOS transistor. Therefore, it is possible to remarkably suppress interaction of the dopant in the silicon layer with the silicide layer during the annealing to be generally performed for a longer time than a heat treatment to be performed when the silicide layer is to be formed. When the second aspect is to be applied to a method of manufacturing a dual CMOS transistor sharing both gate electrodes, mutual diffusion of the dopant through the silicide layer is not caused at all because the silicide layer itself has not been formed during the annealing treatment. Consequently, the depletion of the silicon layer can be suppressed remarkably. Accordingly, it is possible to manufacture a semiconductor device which can surely produce the effect (1).

(3) According to the third aspect of the present invention, a source/drain electrode comprising the source/drain region and the silicide layer formed on the source/drain region can have a low resistance. Consequently, it is possible to manufacture a semiconductor device which can produce the effect (1). First of all, the silicon layer (containing no nitrogen) which will become a part of the gate electrode afterwards is provided on the main surface of the silicon substrate by patterning, and nitrogen ions are then implanted into the whole main surface of the silicon substrate. Consequently, the nitrogen can be introduced into both the silicon layer constituting a part of the gate electrode of the MOS transistor and the silicon layer constituting the source/drain region at the same time.

(4) According to the fourth aspect of the present invention, the silicon layer containing nitrogen all over can be formed. Consequently, the dopant in the silicon layer can also be prevented from being moved and diffused to the silicon substrate. For example, when the dopant is boron and the silicon layer and the silicide layer are applied to the gate electrode of the MOS transistor, it is possible to manufacture a MOS transistor which can surely be operated with a designed and predetermined threshold voltage.

(5) According to the fifth aspect of the present invention, the dopant in the silicon layer can be prevented from being moved and diffused to the silicon substrate by the nitrogen in the insulating film. For example, when the dopant is boron and the silicon layer and the silicide layer are applied to the gate electrode of the MOS transistor, it is possible to manufacture a MOS transistor which can surely be operated with a designed and predetermined threshold voltage.

(6) According to the sixth aspect of the present invention, it is possible to provide a semiconductor device which can produce any of the effects (1) to (5).

(7) According to the seventh aspect of the present invention, a resistance of the silicide layer is lower than that of the silicide layer formed on the silicon layer having no nitrogen distributed layer due to the above-mentioned function of the nitrogen in the nitrogen distributed layer. Similarly, when the dopant is boron (B), the depletion of the silicon layer is suppressed more than that of the silicon layer having no nitrogen distributed layer. In this case, when a concentration of the boron is to be controlled in consideration of the above-mentioned suction, it is possible to obtain a silicon layer whose depletion can surely be suppressed.

Thus, the semiconductor device comprises an electrode (including a silicon layer and a silicide layer) having a lower resistance than in the case where the nitrogen distributed layer is not provided. Furthermore, since the depletion of the silicon layer is fully suppressed, the semiconductor device can be operated at a high speed.

(8) According to the eighth aspect of the present invention, the nitrogen distributed layer is provided closer to the silicide layer side than the mean range of the dopant. Furthermore, the dopant is introduced into the silicon layer by the ion implantation. Consequently, the introduction of the dopant, therefore, the arrangement relationship between the dopant and the nitrogen is surely controlled. Accordingly, the semiconductor device can reliably produce the effect (7).

(9) According to the ninth aspect of the present invention, the whole silicon layer contains the nitrogen. In the semiconductor device, therefore, the dopant in the silicon layer can be prevented from being moved and diffused toward the opposite side to the silicide layer at the time of the formation of silicide. For example, when the dopant is boron and the silicon layer and the silicide layer are applied to the gate electrode of the MOS transistor, it is possible to provide a MOS transistor which can surely be operated with a designed and predetermined threshold voltage.

(10) According to the tenth aspect of the present invention, it is possible to provide a MOS transistor which can produce any of the effects (7) to (9).

(11) According to the eleventh aspect of the present invention, the nitrogen in the insulating film can prevent the dopant (for example, boron) in the silicon layer from being moved and diffused to the silicon substrate in the semiconductor device. Accordingly, it is possible to provide a MOS transistor which can surely be operated with a designed and predetermined threshold voltage.

(12) According to the twelfth aspect of the present invention, it is possible to provide a MOS transistor in which the source electrode and/or the drain electrode can produce any of the effects (7) to (9). In this case, when the source electrode and/or the drain electrode are/is applied to the semiconductor device according to the tenth or eleventh aspect of the present invention, it is possible to provide a MOS transistor which can execute predetermined operating characteristics more reliably.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view typically showing a structure of a semiconductor device according to a first embodiment;

FIGS. 2 to 10 are longitudinal sectional views typically illustrating a method of manufacturing the semiconductor device according to the first embodiment;

FIG. 11 is a longitudinal sectional view typically showing a structure of a semiconductor device according to a second embodiment;

FIGS. 12 and 13 are longitudinal sectional views typically illustrating a method of manufacturing the semiconductor device according to the second embodiment;

FIG. 14 is a longitudinal sectional view typically showing another structure of the semiconductor device according to the second embodiment;

FIG. 15 is a longitudinal sectional view typically showing a structure of a semiconductor device according to a third embodiment;

FIG. 16 is a longitudinal sectional view typically showing a structure of a semiconductor device according to a fourth embodiment; and

FIGS. 17 to 21 are longitudinal sectional views typically illustrating a method of manufacturing a semiconductor device according to the background art.

### DESCRIPTION OF THE PREFERRED EMBODIMENTS

<First Embodiment>

FIG. 1 is a longitudinal sectional view typically showing a dual gate CMOS transistor according to a first embodiment. As shown in FIG. 1, a PMOS transistor region and an NMOS transistor region are divided by an isolation oxide film 101 provided on a surface or a main surface of a silicon substrate 1. An n-well 1W having a predetermined depth from the surface is formed in the PMOS transistor region. Similarly, a p-well 51W is formed in the NMOS transistor region. Silicon oxide films (hereinafter referred to as “oxide films”) 2 and 52 acting as gate insulating films are provided in predetermined regions on surfaces of the wells 1W and 51W or the surfaces of the silicon substrate 1.

Polysilicon layers (silicon layers) 3 and 53 are provided on surfaces of the silicon oxide films 2 and 52 which are opposite to the silicon substrate 1, and cobalt silicide (CoSi₂) layers (hereinafter referred to as “silicide layers”) 11 and 61 are provided on surfaces of the polysilicon layers 3 and 53 which are opposite to the silicon substrate 1. The silicon layers and the silicide layers provided on the silicon layers constitute “gate electrodes” of a MOS transistor. (see gate electrodes 5 and 55 shown in FIG. 1). In particular, nitrogen distributed layers 3N and 53N containing nitrogen are formed in the vicinity of the surfaces of the polysilicon layers 3 and 53 on the silicide layer 11 and 61 sides, for example, in a region having a depth from the surfaces of about 100 Angstroms. Furthermore, a boron distributed layer 3B containing boron (B) is formed closer to the silicon substrate 1 side than the nitrogen distributed layer 3N in the polysilicon layer 3. Similarly, a phosphorus distributed layer 53P containing phosphorus (P) is formed closer to the silicon substrate 1 side than the nitrogen distributed layer 53N in the polysilicon layer 53.

For example, gate sidewall-spacers (hereinafter referred to as “spacers”) 7 and 57 which are formed of a silicon oxide film are provided to interpose the polysilicon layers 3 and 53 (or the gate electrodes 5 and 55) and silicon oxide films 2 and 52 on both sides thereof on the surface of the silicon substrate 1. A p⁻-type layer 6 containing a p-type dopant (for example, boron) is formed in a region having a predetermined depth from the surface of the n-well 1W just below the spacer 7 in the n-well 1W, and an n⁻-type layer 56 containing an n-type dopant (for example, phosphorus) is formed in the same region of the well 51W. The p⁻-type layer 6 and the n⁻-type layer 56 are so-called LDD layers.

Silicide layers 10 and 60 are extended in a direction apart from ends of the spacers 7 and 57 in contact therewith on the surfaces of the wells 1W and 51W. A p⁺-type layer 8 containing a p-type dopant is formed in a region having a predetermined depth in contact with a silicide layer 10 in the n-well 1W just below the silicide layer 10, and an n⁺-type layer 58 containing an n-type dopant is formed in the well 51W. A dopant concentration of each of the p⁺-type layer 8 and the n⁺-type layer 58 is higher than that of each of the p⁻-type layer 6 and the n⁻-type layer 56. The p⁻-type layer and p⁺-type layer and the n⁻-type layer and n⁺-type layer will generally be referred to as “source/drain regions” respectively (see source drain regions 9 and 59 shown in FIG. 1), and components comprising the source/drain regions and the silicide layer will be referred to as “source/drain electrodes” (see source/drain electrodes 15 and 65 shown in FIG. 1).

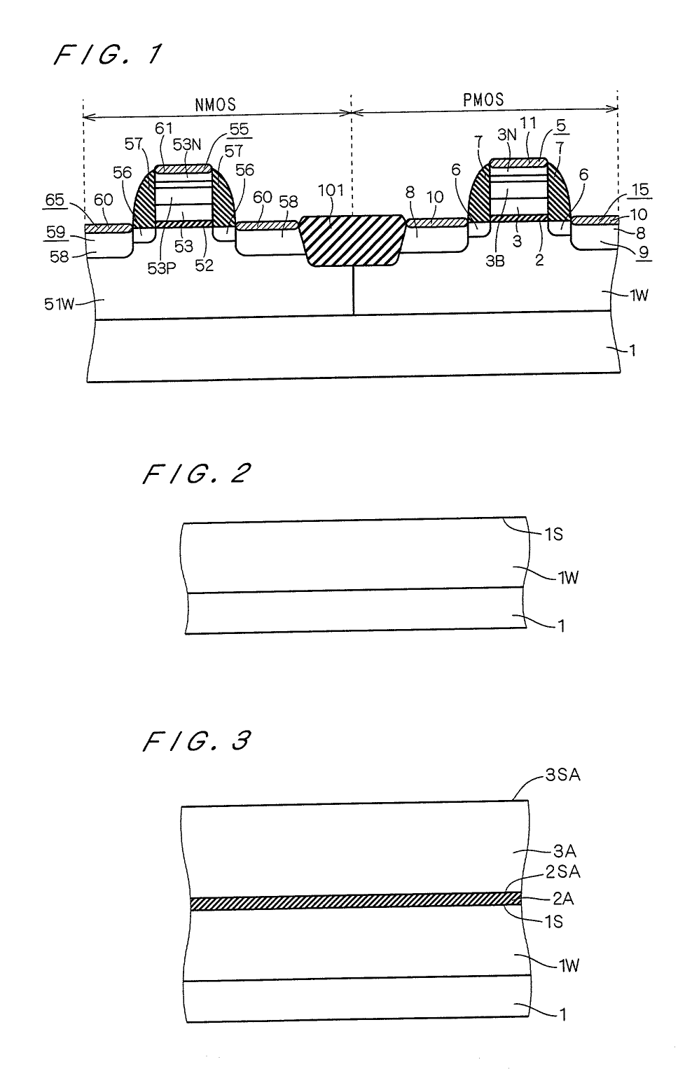

Next, a method of manufacturing a PMOS transistor in the dual CMOS transistor of FIG. 1 will be described with reference to FIGS. 2 to 10. FIGS. 2 to 10 are longitudinal sectional views typically illustrating each step of the manufacturing method. While the method of manufacturing a PMOS transistor will be described below, an NMOS transistor can be manufactured by the same method as the following manufacturing method and the dual CMOS transistor shown in FIG. 1 can also be manufactured by a combination of both manufacturing methods in the same manner as a conventional manufacturing method.

First of all, a silicon substrate 1 is prepared. As shown in FIG. 2, an n-type impurity, for example, phosphorus (P) is implanted into a region having a predetermined depth from a surface (main surface) 1S of the silicon substrate 1, thereby forming an n-well 1W. An annealing treatment may be performed (at a temperature of about 800 to 900° C. for about 30 minutes, for example) after each ion implanting step or collectively after a plurality of ion implanting steps.

Next, the surface 1S of the silicon substrate 1 (the surface of the n-well 1W) in the state of FIG. 2 is oxidized by thermal oxidation or the like, thereby forming a silicon oxide film 2A (see FIG. 3). It is assumed that the surface 1S obtained after the formation of the oxide film 2A is a surface of a silicon material of the silicon substrate forming an interface with the oxide film 2A (including the same oxide film formed after the oxide film 2A is subjected to various treatments). A polysilicon layer 3A (having a thickness of about 2000 Angstroms, for example) is formed on an exposed surface 2SA of the oxide film 2A by a CVD method, for example (see FIG. 3).

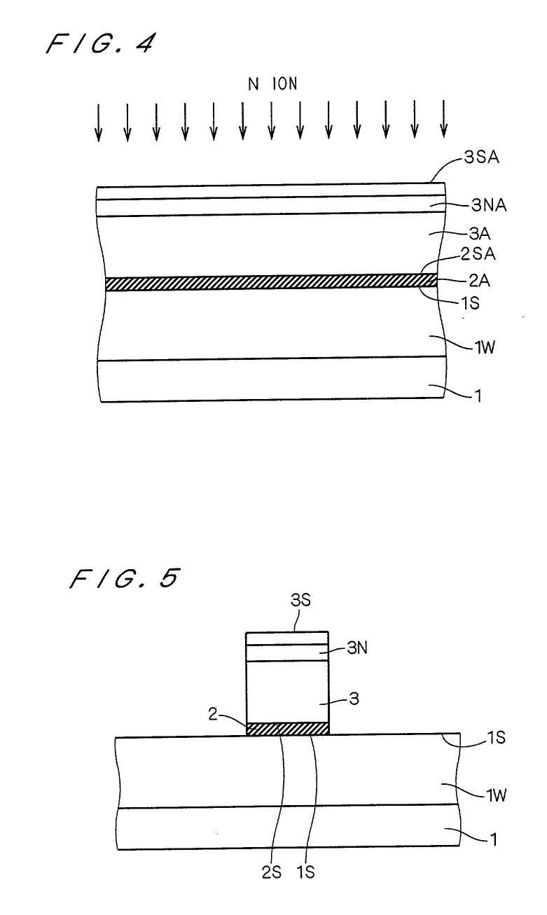

Then, nitrogen is introduced from the exposed surface 3SA side of the polysilicon layer 3A by ion implantation, thereby forming a nitrogen distributed layer 3NA (which will become a nitrogen distributed layer 3N afterwards) in a polysilicon layer 3 as shown in FIG. 4. At this time, an accelerating energy is set to about 10 keV or less and a dose is set to about 2E15/cm², for example, so that a mean implantation depth (or range) of the nitrogen from the surface 3SA can be set to about 100 Angstroms or less. In this case, a nitrogen concentration of the nitrogen distributed layer 3N can be set comparatively higher (than a polysilicon layer of a conventional MOS transistor), for example, to about 2E20/cm³.

Thereafter, the polysilicon layer 3A and the oxide film 2A are subjected to patterning by using a photolithography technology and an anisotropic etching technology. Consequently, the polysilicon layer 3 and the silicon oxide film 2 which are shown in FIG. 5 are formed. As shown in FIG. 5 (and FIG. 1), the polysilicon layer 3 has the nitrogen distributed layer 3N formed by a part of the nitrogen distributed layer 3NA. Furthermore, a portion remaining in the surface 3SA will be hereinafter referred to as a “surface 3S”. In addition, there is also a manufacturing method in which a part of the oxide film 2A is caused to remain at the present step.

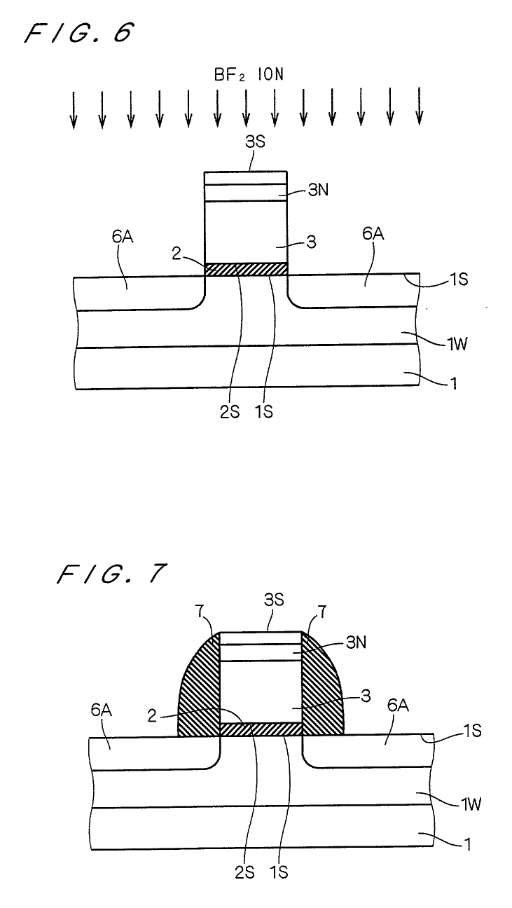

Next, a p-type dopant, for example, boron is implanted as boron difluoride (BF₂) ions into the silicon substrate 1 by ion implantation, thereby forming a p⁻-type layer 6A in the n-well 1W excluding a portion covered with the polysilicon layer 3 and the oxide film 2 as shown in FIG. 6. At this time, an accelerating energy is set to about 10 keV and a dose is set to about 1E14/cm², for example. At the present ion implanting step, the boron is also introduced into the polysilicon layer 3. In the following description, boron ions and boron compound ions will generally be referred to as “boron ions”.

Then, a TEOS oxide film is deposited by a CVD method to wholly cover the exposed surface 1S, the polysilicon layer 3 and the oxide film 2. The TEOS oxide film is subjected to anisotropic etch back to form a spacer 7 shown in FIG. 7.

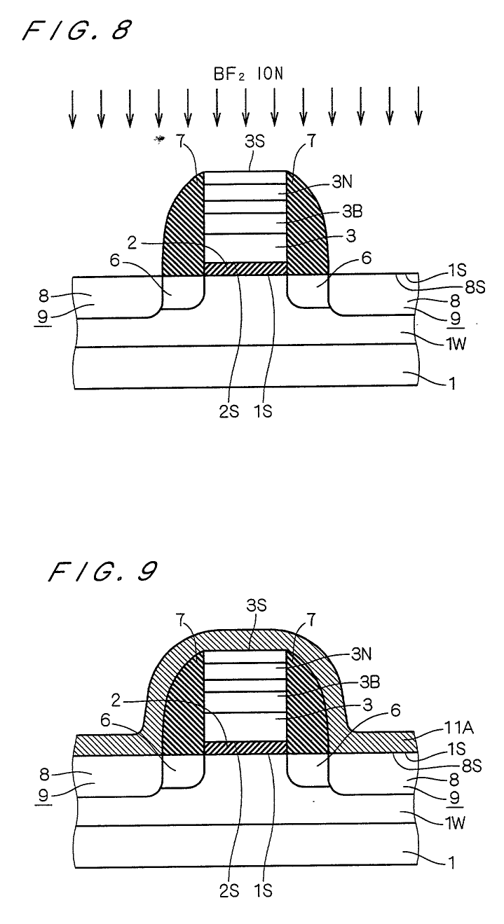

As shown in FIG. 8, the BF₂ ions are implanted at an accelerating energy of about 20 to 30 keV and a dose of about 1E15/cm², for example, thereby forming a p⁺-type layer 8 in a region excluding the portion covered with the polysilicon layer 3 (and the oxide film 2) and the spacer 7 in the surface 1S of the n-well 1W. A surface of the p⁺-type layer 8 in the surface 1S will also be referred to as a “surface 8S”. A portion provided just below the spacer 7 in the p⁻-type layer 6A (see FIG. 7), that is, a portion which remains in the p⁻-type layer 6A after the present step and has a lower dopant concentration than in the p⁺-type layer 8 forms a p⁻-type layer 6.

As shown in FIG. 8, the boron is also introduced into the polysilicon layer 3 to form a boron distributed layer 3B at the ion implanting step. At this time, depending on the above-mentioned implanting conditions, the boron distributed layer 3B is formed in the vicinity of a region having a mean implantation depth (or range) from the surface 3S of the polysilicon layer 3 of about 150 Angstroms or more, and therefore, closer to the silicon substrate 1 side than the nitrogen distributed layer 3N. Furthermore, a concentration of the boron distributed layer 3B is in order of about 10²¹ to 10²²/cm³.

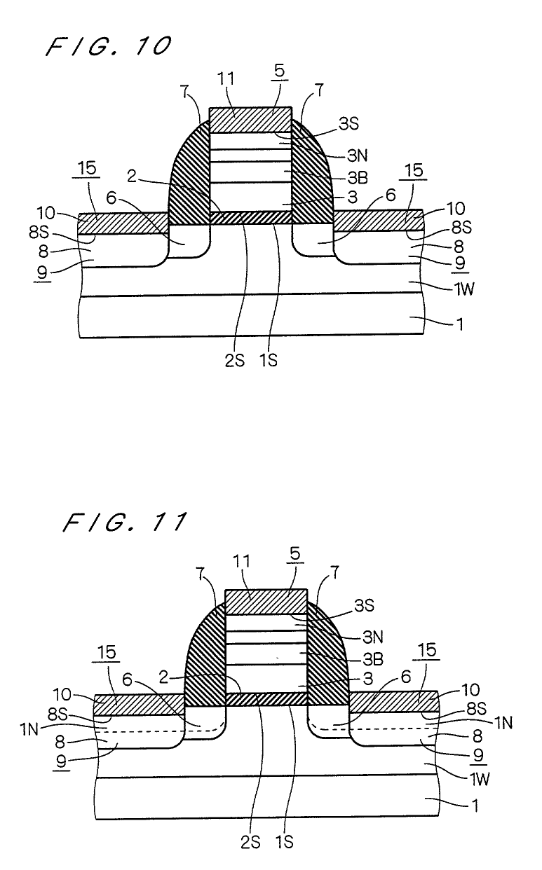

As shown in FIG. 9, next, a cobalt (Co) layer (metal layer) 11A, for example, is deposited by sputtering or the like to wholly cover the exposed surfaces 1S and 3S and the spacer 7. Metals such as titanium (Ti), tungsten (W), molybdenum (Mo), tantalum (Ta), nickel (Ni), platinum (Pt) and the like may be used in place of the cobalt. In particular, it is desirable that a heat treating step such as an annealing step for the source/drain region 9 should be completed before a step of forming the cobalt layer 1A. Then, the heat treatment is carried out to cause a silicide reaction between the cobalt layer 11A and the polysilicon layer 3 and p⁺-type layer 8. At this time, the heat treatment is carried out by so-called RTA (Rapid Thermal Annealing) at a temperature of 1000° C. for about 10 seconds (which is a shorter time than an annealing time taken to form the source/drain region 9), for example. The heat treatment may be performed by the RTA plural times. Also in such a case, a time taken to perform the heat treatment plural times is shorter than the annealing time taken to form the source/drain region 9. The silicide reaction is selectively performed in self-alignment only between the silicon material and the cobalt (a so-called salicide reaction). Therefore, an unreacted portion of the cobalt layer 11A is removed after the salicide reaction so that cobalt silicide layers 10 and 11 shown in FIG. 10 are obtained on the surfaces 8S and 3S, respectively. After the silicide layer is formed, surfaces of the silicon materials of the polysilicon layer 3 and the silicon substrate 1 which make interfaces with the silicide layers 11 and 10 will be referred to as a “surface 1S” and a “surface 8S”, respectively.

The dopant such as the boron is thermally diffused or moved through a vacancy in the silicon. In this case, the nitrogen distributed layers 3N and 53N in the polysilicon layers 3 and 53 of the dual CMOS transistor according to the first embodiment are present closer to the silicide layer 11 and 61 sides than the boron distributed layer 3B and the phosphorus distributed layer 53P as shown in FIG. 1. For this reason, the nitrogen in the nitrogen distributed layers 3N and 53N are thermally diffused more quickly than the boron and the phosphorus to fill the vacancy in the polysilicon at the heat treating step. Therefore, the dopant concentration in the vicinity of the surface 3S of the polysilicon layer 3 is kept almost equal to that obtained before the heat treating step is carried out. Accordingly, it is possible to fully suppress a phenomenon in which each dopant in the polysilicon layer 3 impedes the silicide reaction. Therefore, resistances of the silicide layers 11 and 61 of the MOS transistor are reduced more sharply than those of the conventional MOS transistor having neither of the nitrogen distributed layers 3N and 53N. Such a respect is also adequate for other p-type or n-type dopants. In particular, the thermal diffusion speed of the boron is higher than that of any other dopant. Therefore, in the case where the boron is used for the dopant of the PMOS transistor, the above-mentioned effect of suppressing the impediment of the silicide reaction can remarkably be obtained. Thus, the resistance of the silicide layer 11 can surely be reduced.

For the same reason, furthermore, the nitrogen distributed layer 3N can surely suppress the sucking phenomenon of the boron during the silicide reaction and control a reduction in the boron concentration of the polysilicon layer 3 or the depletion of the polysilicon layer 3. Consequently, the resistance of the polysilicon layer 3 can be reduced more sharply than that of the above-mentioned conventional MOS transistor.

Thus, the resistance of the gate electrodes (comprising the silicon layer and the silicide layer) 5 and 55 of the MOS transistor are reduced more noticeably than in the above-mentioned conventional MOS transistor. Accordingly, the PMOS transistor and the NMOS transistor can save electric power.

In addition, the effect of suppressing the sucking phenomenon can cause the PMOS transistor to surely be operated at a designed and predetermined threshold voltage without generating a fluctuation in the threshold voltage of the PMOS transistor. As a result, the PMOS transistor can be operated at a higher speed than the conventional MOS transistor.

In this case, when the nitrogen is introduced into the polysilicon layers 3 and 53 before the step of performing the salicide reaction, it is possible to manufacture a MOS transistor which can produce the above-mentioned effect. Furthermore, if the nitrogen concentration of the nitrogen distributed layer is in order of about 10¹⁸/cm³ or more, the same layer can produce such an effect.

In consideration of the fact that the diffusion speed of the boron in the cobalt silicide is lower than that in tungsten silicide (WSi₂) (see FIG. 1 of IEEE' 91 “Technology Limitation for N⁺/P⁺ Polycide Gate CMOS due to Lateral Diffusion in Silicide/Polysilicon Layers”), even if boron is moved and diffused into a silicide layer, the diffusion of the boron in the silicide layer can be more controlled in the PMOS transistor according to the first embodiment in which cobalt is applied to a metal layer than the case where tungsten is used for the metal layer.

Also in the conventional MOS transistor, N ions are implanted into the polysilicon layer constituting the gate electrode in some cases. However, such nitrogen introduction is intended to control a phenomenon (a punch through of the boron) in which the boron is moved and diffused into the silicon substrate beyond a gate insulating film, for example. Therefore, a nitrogen distributed layer in the polysilicon layer is formed in a portion (gate electrode side) having a depth equal to or greater than a distribution depth (range) of the boron. Accordingly, a position where the nitrogen distributed layer is to be formed is clearly different from that in the MOS transistor according to the first embodiment.

Japanese Patent Application Laid Open Gazette No. 7-30108 has disclosed a method of manufacturing a MOS transistor comprising a step of implanting nitrogen into a polysilicon layer constituting a part of a gate electrode (which will be hereinafter referred to as a prior art \mathring{1}. In the manufacturing method according to the prior art \mathring{1}, a silicide material itself is deposited to form a silicide layer constituting a gate electrode in the early stage of a process of manufacturing the MOS transistor. For this reason, in the case where a dual gate CMOS transistor sharing both gate electrodes is to be manufactured, the above-mentioned nitrogen introduction is carried out in order to suppress mutual diffusion of a dopant in each of polysilicon layers of both MOS transistors through the silicide layer at a heat treating step to be performed after the formation of the silicide layer, for example, during an annealing treatment for a source/drain region. As described above, however, the manufacturing method according to the prior art \mathring{1} is greatly different from the manufacturing method according to the first embodiment in which the silicide layer constituting a part of the gate electrode is formed by the silicide reaction (salicide reaction) in the final stage of the manufacturing process in that the silicide material itself is deposited to form the silicide layer in the early stage of the process of manufacturing the MOS transistor.

In this case, the manufacturing method according to the first embodiment has the following noticeable predominance for the prior art \mathring{1} due to the difference in the step of forming the silicide layer. More specifically, a heat treatment such as the annealing step for the source/drain region 9 can be completed before the step of forming the cobalt layer 11A in the manufacturing method according to the first embodiment. In such a case, accordingly, (i) since the silicide layer itself has not been formed at the time of the heat treatment such as the annealing step for the source/drain region 9, the mutual diffusion of the dopant through the silicide layer at the annealing step or the like which occurs when the above-mentioned dual gate CMOS transistor is to be manufactured is not caused at all. Accordingly, the depletion of the polysilicon layer is not caused by such mutual diffusion. Furthermore, (ii) if the annealing step and the like for the source/drain region 9 are completed before the step of forming the cobalt layer 11A, the cause for interaction of the dopant in the polysilicon layer 3 with the silicide layer 11 can be eliminated at steps other than the silicide reaction step. Accordingly, the depletion of the polysilicon layer caused by such interaction can fully be suppressed. In this case, it is apparent that the effects (i) and (ii) have very good results in consideration of the fact that an annealing time taken in the source/drain region is generally longer than a heat treating time taken for the silicide reaction.

<Second Embodiment>

A structure of a PMOS transistor and a method of manufacturing the PMOS transistor according to a second embodiment will be described below with reference to FIGS. 11 to 13. Since the structure of the PMOS transistor and the method of manufacturing the PMOS transistor are based on those of the PMOS transistor according to the first embodiment described above, features of the PMOS transistor will chiefly be described. For this reason, the same components as the above-mentioned components have the same reference numerals and their description will be cited. Such a respect is the same in the following description.

As shown in FIG. 11, the PMOS transistor according to the second embodiment further comprises a nitrogen distributed layer 1N which is equivalent to the above-mentioned nitrogen distributed layer 3N in a region having a predetermined depth from a surface 1S in a source/drain region 9. The nitrogen distributed layer 1N is formed by the following manufacturing method.

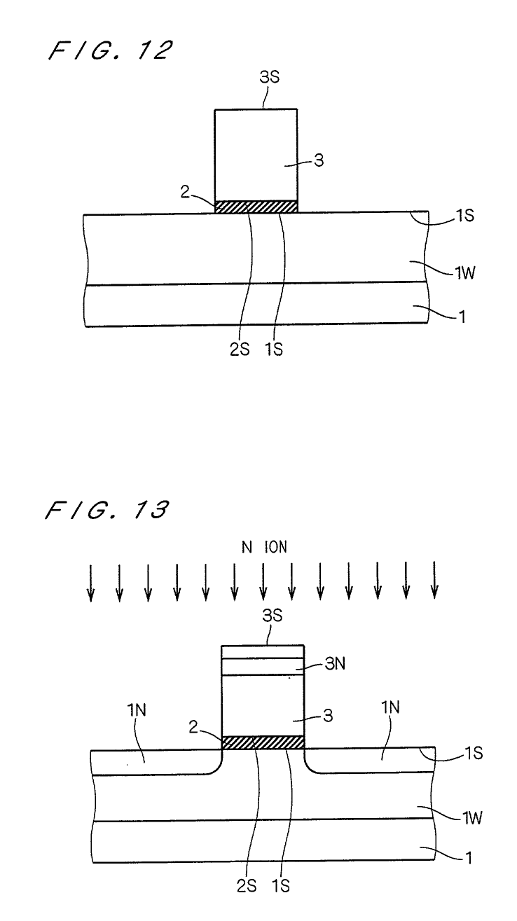

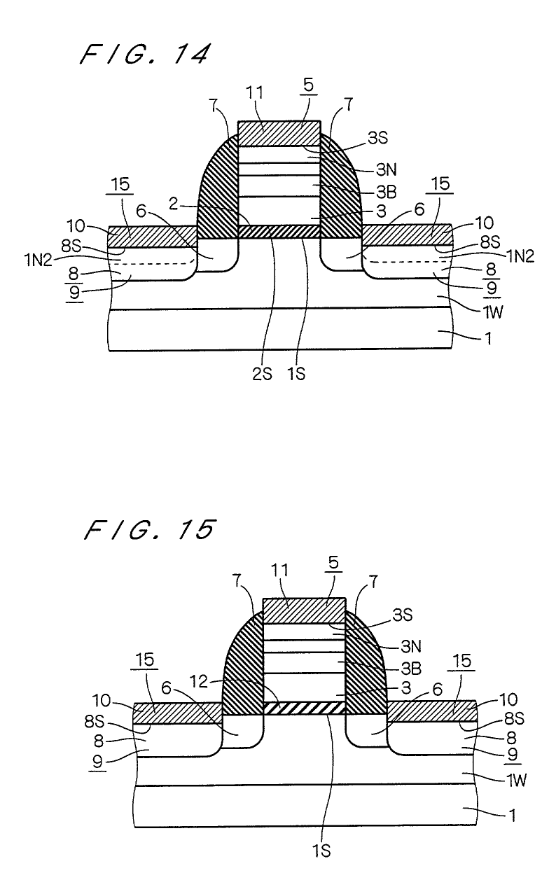

In the same manner as the manufacturing method according to the first embodiment, first of all, a silicon substrate 1 set in the state shown in FIG. 3 is prepared. In the manufacturing method, the N ion implanting step to be performed successively in the manufacturing method according to the first embodiment is not carried out but a polysilicon layer 3A and an oxide film 2A are subjected to patterning, thereby forming a polysilicon layer 3 and an oxide film 2 shown in FIG. 12. As is seen from a comparison between FIGS. 12 and 5, therefore, the polysilicon layer 3 according to the second embodiment shown in FIG. 12 has no nitrogen distributed layer 3N in FIG. 5.

As shown in FIG. 13, then, N ions are implanted into the whole surface 1S of the silicon substrate 1 at an accelerating energy of about 10 keV or less and a dose of about 2E15/cm². By such implantation, the nitrogen distributed layer 3N is formed in the polysilicon layer 3, and the nitrogen distributed layer 1N is formed in the surface 1S of the silicon substrate 1 excluding a portion covered with the polysilicon layer 3 and the oxide film 2. At this time, mean depths from the surfaces 1S and 3S of the nitrogen distributed layers 1N and 3N are about 100 Angstroms or less.

The same steps as in the manufacturing method according to the first embodiment, for example, the first and second BF₂ ion implanting steps are executed, thereby forming each layer and the like. Thus, the PMOS transistor shown in FIG. 11 is finished. At the same steps, the nitrogen distributed layer can be formed in the source/drain region 59 of the NMOS transistor (see FIG. 1).

In the same manner as the nitrogen distributed layer in the polysilicon layer, the nitrogen distributed layer in the source/drain region can suppress the interaction of a dopant in a source/drain region with a silicide layer provided on the same region during a silicide reaction (salicide reaction) more sharply than the conventional MOS transistor. Consequently, a source/drain electrode having a low resistance can be formed. Since the source/drain region can be regarded as a “silicon layer”, the source/drain electrode comprises the silicon layer and the silicide layer provided on the silicon layer. According to the present MOS transistor, therefore, electric power saving can further be promoted as compared with the MOS transistor in accordance with the first embodiment.

Furthermore, the nitrogen distributed layer in the source/drain region can reduce a junction leakage current. In a PMOS transistor using boron as a dopant, it is possible to suppress a sucking phenomenon of the boron when a source/drain electrode is to be formed. As a result, it is possible to obtain a MOS transistor which can surely exhibit predetermined operating characteristics. In this case, the MOS transistor can be driven at a high speed.

When the N ion implanting step is carried out after the polysilicon layer is formed by the patterning and before a heat treating step for the salicide reaction is performed, the nitrogen distributed layer can be formed in the source/drain region. Thus, it is possible to manufacture a MOS transistor which can produce the above-mentioned effects. In this case, when the kind of ions is changed in the same reactor to continuously carry out the N ion implanting step according to the present manufacturing method and the first or second BF₂ ion implanting step for forming the source/drain region (these steps can be performed in any order), a manufacturing time can be more shortened than in the manufacturing method according to the first embodiment. Even if the nitrogen distributed layer is formed in the source/drain region of one of source and drain electrodes, the above-mentioned effects can be obtained to a constant degree.

FIG. 14 shows a PMOS transistor manufactured by carrying out the N ion implanting step before or after the second BF₂ ion implanting step is performed (that is, after a spacer 7 is formed). As shown in FIG. 14, the PMOS transistor does not have a nitrogen distributed layer in a p⁻-type layer 6 provided just below the spacer 7 but has a nitrogen distributed layer 1N2 only in a region of a p⁺-type layer 8, the nitrogen distributed layer 1N2 being equivalent to the nitrogen distributed layer 1N. The PMOS transistor can also produce the above-mentioned effects.

Japanese Patent Application Laid Open Gazette No. 9-8297 has disclosed a manufacturing method comprising the step of implanting N ions into a source/drain region (hereinafter referred to as a prior art \mathring{2}). According to the prior art \mathring{2}, in the case where cobalt or nickel is used as a metal material for a silicide layer, a silicide reaction is uniformly advanced on an interface of the metal material and a silicon material. In detail, a polysilicon layer equivalent to the polysilicon layer 3 is formed on a silicon substrate, and a source/drain region is formed in the silicon substrate, and the metal material is then provided by sputtering on the polysilicon layer which is the silicon material and the source/drain region. Thereafter, a natural oxide film over a surface of the silicon material which is present on an interface of the silicon material and the deposited metal layer and impedes a uniform silicide reaction in the interface is ground by implanting the N ions into the interface. After the grinding step, the silicide reaction (salicide reaction) is carried out. Consequently, a flat silicide layer having a uniform thickness can be formed.

In this case, the prior art \mathring{2} has proposed that the N ions are implanted after a cobalt layer or the like is formed as described above in consideration of the object of the N ion implantation. On the other hand, in the manufacturing method according to the second embodiment, the N ion implanting step for forming the nitrogen distributed layer 3N can be executed after the polysilicon layer 3 is formed by anisotropic etching and before a heat treating step for performing the salicide reaction with respect to the metal layer 11A is carried out. Therefore, the degree of freedom of a manufacturing process is very great. As described above, therefore, even if the N ion implanting step is introduced, an increase in a manufacturing time can be prevented more sharply than in the manufacturing method according to the prior art \mathring{2}.

In the prior art \mathring{2}, the N ions are implanted through the cobalt layer or the like which is the metal material. For this reason, it has been proposed that the N ion implantation should be performed at a comparatively high accelerating energy of 10 keV or more and a comparatively small dose of about 1E15/cm² (in order to grind the natural oxide film). On the other hand, in the manufacturing method according to the second embodiment, the N ions are implanted at an energy (about 10 keV or less) lower than the accelerating energy and a dose (about 2E15/cm²) higher than the dose according to the prior art \mathring{2} in order to suppress interaction of a dopant in silicon with the silicide layer. Thus, obvious differences between both N ion implanting steps are appreciated on the N ion implanting conditions.

<Third Embodiment>

FIG. 15 is a longitudinal sectional view showing a PMOS transistor according to a third embodiment. As shown in FIG. 15, the PMOS transistor comprises a silicon oxy-nitride film (SiON) 12 which is a gate insulating film containing nitrogen in place of the silicon oxide film 2 in the PMOS transistor of FIG. 10. The silicon oxy-nitride film 12 can be formed at the following forming steps.

First of all, a heat treatment is carried out for a surface 1S of a silicon substrate 1 in a nitrogen containing atmosphere such as an NO gas atmosphere in place of the step of forming the silicon oxide film 2A described above (see FIG. 3). At this time, a nitrogen concentration of a silicon oxy-nitride film is set almost equal to that of the above-mentioned nitrogen distributed layer. The silicon oxy-nitride film obtained by the heat treatment is subjected to patterning by anisotropic etching at a subsequent step of forming a spacer 7. Thus, the silicon oxy-nitride film 12 is formed. The manufacturing process according to the first embodiment can be applied to steps other than the heat treatment in the NO gas atmosphere.

The silicon oxy-nitride film has greater boron diffusion preventing function than a silicon oxide film. Therefore, the silicon oxy-nitride film 12 can sharply suppress a punch through of the boron in the polysilicon layer 3 into the silicon substrate 1 at the heat treating step. As a result, the PMOS transistor can surely be operated at a high speed with a designed and predetermined threshold voltage. By using the silicon oxy-nitride film for the gate insulating film, furthermore, it is possible to produce the effect that a higher hot carrier resistance is obtained than in a MOS transistor having the gate insulating film formed by the silicon oxide film (such an effect is not restricted to the case where a dopant is boron).

The above-mentioned Japanese Patent Application Laid Open Gazette No. 7-30108 has disclosed a technique (hereinafter referred to as a prior art \mathring{3}) in which a gate insulating film is formed and a polysilicon layer is formed on the gate insulating film and N₂ plasma irradiation is then carried out over surfaces of the gate insulating film and the polysilicon layer respectively, thereby nitriding the surfaces. By such a nitriding process, a region containing nitrogen is formed on an interface of the gate insulating film/the polysilicon layer and an interface of the polysilicon layer/silicide layer (which is formed by depositing a silicide material itself as described above), so that the punch through of the boron in a gate electrode of the PMOS transistor and mutual diffusion of the dopant in both gate electrodes of a dual gate CMOS transistor can be suppressed. However, the region containing nitrogen which is formed by the N₂ plasma treatment is very thin. On the other hand, the silicon oxy-nitride film 12 forming the gate insulating film according to the third embodiment contains the nitrogen all over. Due to such a difference, it is apparent that the effect of suppressing the punch through of the boron by the silicon oxy-nitride film 12 is greater than that on the nitride interface according to the prior art \mathring{3}. Moreover, an additional step such as the N₂ plasma irradiation is not required in the manufacturing method in accordance with the second embodiment, and the number of manufacturing steps is not increased for the manufacturing method according to the first embodiment. As described above, the interaction itself of the dopants in the polysilicon layers 3 and 53 with the silicide layers 11 and 61 can be controlled by the above-mentioned nitrogen distributed layers 3N and 53N.

<Common Variant 1 of First to Third Embodiments>

The following variant 1 can be applied to each of the manufacturing methods according to the first to third embodiments. After a step of forming a polysilicon layer 3A and before a step of patterning the polysilicon layer 3A, a boron distributed layer is formed in the vicinity of a region having an implantation depth from a surface 3S of about 330 Angstroms in the polysilicon layer 3A (or a polysilicon layer 3). The boron distributed layer is formed by implanting BF₂ ions into the polysilicon layer 3A at an accelerating energy of about 10 keV and a dose of about 1E15/cm², for example. The BF₂ ion implanting step and an N ion implanting step can be carried out in any order. Boron in the boron distributed layer suppresses the depletion of the polysilicon layer 3 more sharply and reliably during a silicide reaction than each of the manufacturing methods according to the first to third embodiments. Such a boron distributed layer is deeper than the above-mentioned nitrogen distributed layer (having a mean depth of about 100 Angstroms or less). Therefore, the boron in the boron distributed layer is diffused to the surface 3S of the polysilicon layer 3 with difficulty and less interaction with a silicide layer 11 is obtained. Even if the boron is diffused to the surface 3S side, the nitrogen distributed layer 3N can fully suppress such interaction.

<Fourth Embodiment>

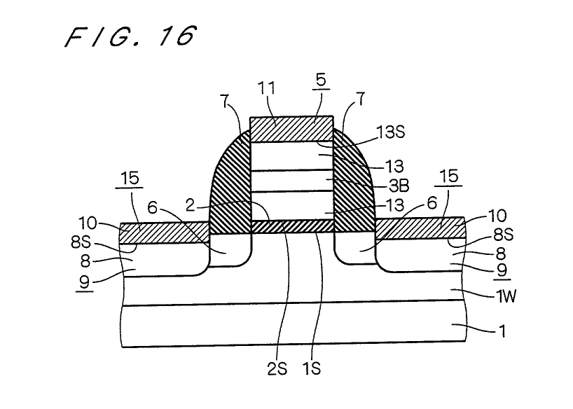

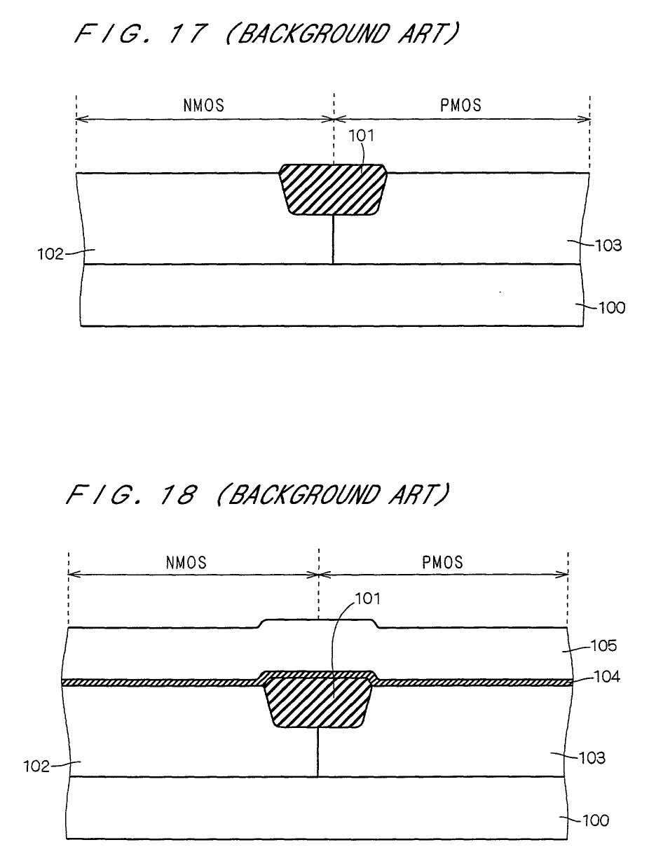

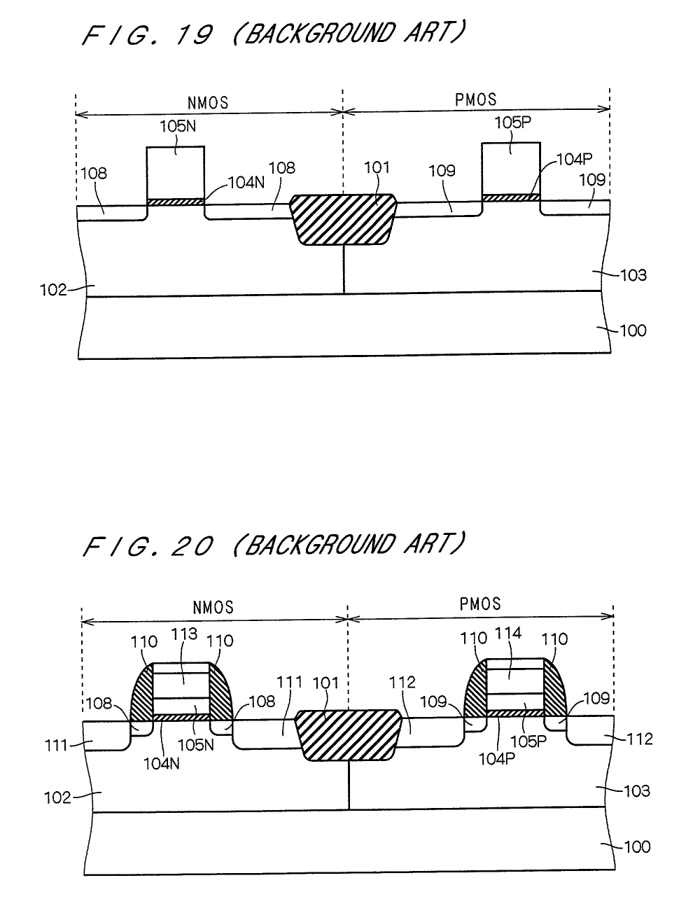

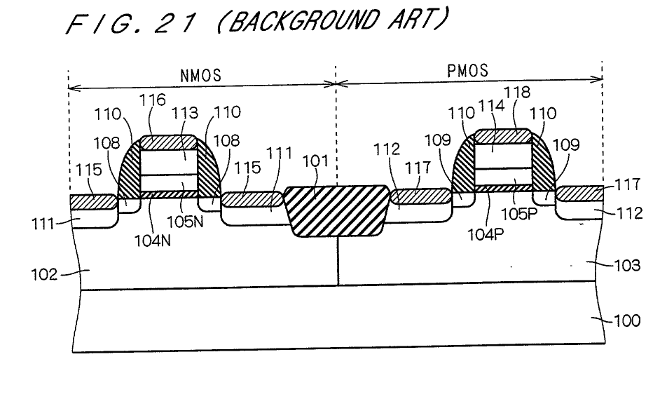

FIG. 16 is a longitudinal sectional view showing a PMOS transistor according to a fourth embodiment. As shown in FIG. 16, the PMOS transistor comprises a polysilicon layer (silicon layer) 13 in which a whole portion other than at least a boron distributed layer 3B is doped with nitrogen in place of the polysilicon layer 3 in the PMOS transistor shown in FIG. 10 (a surface 13S shown in FIG. 16 corresponds to the above-mentioned surface 3S). A nitrogen concentration of the polysilicon layer 13 is equal to that of a nitrogen distributed layer 3N. The polysilicon layer 13 which is doped with nitrogen is formed at the following forming steps.

First of all, a polysilicon layer doped with nitrogen is formed on a surface 2SA of an oxide film 2A by a CVD method in place of the step of forming the polysilicon layer 3A (see FIG. 3). In this case, a polysilicon layer containing the nitrogen all over can be formed by using a silane (SiH₄) gas and an ammonia (HN₃) gas as material gases, for example. Then, the N ion implanting step (see FIG. 4) in the manufacturing method according to the first embodiment is not carried out but the step of patterning the polysilicon layer doped with the nitrogen is performed to form a polysilicon layer 13. The manufacturing process according to the first embodiment can be applied to steps other than the step of depositing the polysilicon layer doped with the nitrogen.

According to the polysilicon layer 13, the nitrogen in a shallower region than the boron distributed layer 3B, that is, a region on the silicide layer 11 side can suppress interaction of boron in the boron distributed layer 3B with the silicide layer 11 (such action and effects are the same as in an NMOS transistor). On the other hand, the nitrogen in a deeper region than the boron distributed layer 3B in the polysilicon layer 13, that is, a region on the silicon substrate 1 side can suppress diffusion of the boron into the silicon substrate 1 (a punch through). Accordingly, the MOS transistor can exhibit the above-mentioned effects to surely execute predetermined operating characteristics.

Japanese Patent Application Laid Open Gazette No. 8-31931 has disclosed a dual gate CMOS transistor (hereinafter referred to as a prior art \mathring{4}) in which a polysilicon layer constituting a part of each of gate electrodes comprises (a) a portion formed on a gate insulating film and having each dopant (phosphorus is used for an NMOS transistor and boron is used for a PMOS transistor), and (b) a portion formed between the above-mentioned portion and a silicide layer and containing nitrogen. In a manufacturing method according to the prior art \mathring{4}, both portions having a two-layer structure are formed by a CVD method. However, such a manufacturing method requires a polysilicon layer forming step to be performed twice. Therefore, a manufacturing process may be complicated. Furthermore, a natural oxide film may be formed on an interface between both polysilicon layers at the polysilicon layer forming step to be performed twice.

To the contrary, the polysilicon layer 13 of the MOS transistor according to the fourth embodiment contains nitrogen all over. Therefore, the same layer can be formed at the smaller number of steps than in the manufacturing method according to the prior art \mathring{4} and in a single process. Accordingly, a natural oxide film is not formed in the polysilicon layer.

In the prior art \mathring{4}, the silicide layer is formed by the deposition of a silicide material itself in the early stage of the process of manufacturing the MOS transistor in the same manner as in the above-mentioned prior art \mathring{1}. Therefore, the prior art \mathring{4} is greatly different from each of the manufacturing methods according to the fourth embodiment and the above-mentioned first to third embodiments in which the silicide layer is formed by the salicide reaction in the final stage of the manufacturing process. As described above, according to each of the manufacturing methods in accordance with the fourth embodiment and the above-mentioned first to third embodiments, a heat treatment such as an annealing step for the source/drain region 9 which takes a longer time than a heat treating step for s salicide reaction is completed before the step of forming the cobalt layer 11A so that (i) mutual diffusion of a dopant into a polysilicon layer through the silicide layer is not caused even if a dual gate CMOS transistor sharing a gate electrode is to be manufactured. Furthermore, (ii) the cause of interaction of the dopant in the polysilicon layer 3 with the silicide layer 11 can be restricted to only the silicide reaction step. As a result, it is possible to obtain special effects that the depletion of the polysilicon layer constituting a part of the gate electrode can be suppressed more fully than in the prior art \mathring{4}.

While the first to fourth embodiments (including the variant 1) have been described by taking the boron and the phosphorus as an example of the dopant, other dopants may be used. In this case, it is possible to obtain remarkable effects by using the boron for the dopant as described above.

In particular, it is apparent that an electrode comprising the silicide layer formed by the salicide reaction and the silicon layer containing nitrogen in the vicinity of a surface on the side which is in contact with the silicide layer is not restricted to application to the gate electrode and the source/drain electrode of the MOS transistor but can also be applied to electrodes of other semiconductor devices. In this case, it is possible to provide a semiconductor device capable of exhibiting the same effects as the above-mentioned effects or more by variously combining the first to fourth embodiments (including the variant 1). For example, a so-called punch through of the boron can be suppressed still more surely by combining the silicon oxy-nitride film according to the third embodiment with the silicon layer according to the fourth embodiment.

While the invention has been described in detail, the foregoing description is in all aspects illustrative and not restrictive. It is understood that numerous other modifications and variations can be devised without departing from the scope of the invention.

What is claimed is:

1. A method of manufacturing a semiconductor device comprising the steps of:
(a) preparing a silicon substrate having a main surface;
(b) forming, in a side of said main surface of said silicon substrate, a silicon layer which contains nitrogen at least in the vicinity of a surface of said silicon layer and into which a dopant of a predetermined conductivity type is introduced;
(c) forming a metal layer to cover the whole of said main surface of said silicon substrate after said step (b); and
(d) forming a silicide layer by selectively performing a silicide reaction in self-alignment with respect to a portion of said metal layer which is in contact with silicon.

2. The method of manufacturing a semiconductor device according to claim 1, wherein
said silicon layer constitutes a part of a gate electrode of a MOS transistor,
said method further comprising an annealing step for a source/drain region of said MOS transistor before said step (c).

3. The method of manufacturing a semiconductor device according to claim 1, wherein
said silicon layer is at least one of a layer constituting a part of a gate electrode of a MOS transistor and a source/drain region thereof, and
said nitrogen is introduced into said silicon layer by ion implantation at said step (b).

4. The method of manufacturing a semiconductor device according to claim 1, wherein
said silicon layer constitutes a part of a gate electrode of a MOS transistor, and
said silicon layer is formed in a nitrogen containing atmosphere, thereby causing the whole of said silicon layer to contain the nitrogen therein at said step (b).

5. The method of manufacturing a semiconductor device according to claim 1, wherein
said silicon layer constitutes a part of a gate electrode of a MOS transistor,
said method further comprising a step of forming an insulating film containing nitrogen all over between said silicon substrate and said silicon layer before said step (b).

6. A semiconductor device characterized by being manufactured by said method of manufacturing a semiconductor device according to claim 1.

7. A semiconductor device comprising:
a silicon layer containing a dopant of a predetermined conductivity type and including a nitrogen distributed layer at least in the vicinity of a surface of said silicon layer; and
a silicide layer formed by selectively performing a silicide reaction in self-alignment with respect to a portion of a metal layer provided to cover said silicon layer, which is in contact with said surface of said silicon layer.

8. The semiconductor device according to claim 7, wherein
said dopant is ion-implanted from the side of said surface of said silicon layer to be provided in said silicon layer, and
said nitrogen distributed layer is provided closer to the side of said surface of said silicon layer than the vicinity of a mean range of the implanted dopant.

9. The semiconductor device according to claim 7, wherein
the whole of said silicon layer corresponds to said nitrogen distributed layer.

10. The semiconductor device according to claim 7, wherein
said silicon layer and said silicide layer constitute a gate electrode of a MOS transistor.

11. The semiconductor device according to claim 10, further comprising:
a silicon substrate provided facing a surface opposite to said surface of said silicon layer; and
a gate insulating layer containing nitrogen all over, provided in contact with both said silicon substrate and said silicon layer between said silicon substrate and said silicon layer.

12. The semiconductor device according to claim 7, wherein
said silicon layer and said silicide layer constitute at least one of a source electrode of a MOS transistor and a drain electrode thereof.
